(19) United States
(12) Patent Application Publication
(10) Pub. No.: US 2026/0293756 A1
(43) Pub. Date: Sep. 24, 2026

(54) DIRECT BONDING

(71) Applicants: OKUNO CHEMICAL INDUSTRIES CO., LTD., Osaka-shi, Osaka (JP); The University of Osaka, Suita-shi, Osaka (JP); DAICEL CORPORATION, Osaka-shi, Osaka (JP)

(72) Inventors: Hiroki Seto, Osaka-shi, Osaka (JP); Kei Hashizume, Osaka-shi, Osaka (JP); Yuka Iwamoto, Osaka-shi, Osaka (JP); Norihiko Hasegawa, Osaka-shi, Osaka (JP); Ryuji Yoshida, Osaka-shi, Osaka (JP); Zheng Zhang, Suita-shi, Osaka (JP); Katsuaki Suganuma, Suita-shi, Osaka (JP); Aiji Suetake, Suita-shi, Osaka (JP); Akihiko Happoya, Tokyo (JP)

(73) Assignees: OKUNO CHEMICAL INDUSTRIES CO., LTD., Osaka-shi, Osaka (JP); The University of Osaka, Suita-shi, Osaka (JP); DAICEL CORPORATION, Osaka-shi, Osaka (JP)

(21) Appl. No.: 19/478,047

(22) PCT Filed: Apr. 22, 2024
(86) PCT No.: PCT/JP2024/015690

§ 371 Date: Oct. 23, 2025

(30) Foreign Application Priority Data
Apr. 24, 2023 (JP) 2023-070706

(51) Int. Cl. H10W 80/00; B23K 20/02; B23K 101/40

(52) U.S. Cl. CPC H10W 80/314; B23K 20/02; B23K 2101/40

(57) ABSTRACT

The present invention aims to provide a novel technique for producing a bonded structure using direct bonding. Provided is a bonded structure including a structure 1 and a structure 2 that are bonded together with a metal-plated film therebetween.

### TECHNICAL FIELD

The present invention relates to direct bonding.

### BACKGROUND ART

In the process of mounting a semiconductor element, the semiconductor element is bonded to a substrate with a bonding material. The semiconductor element may be, for example, a next-generation power semiconductor element (e.g., a silicon carbide semiconductor or a gallium nitride semiconductor).

PLT 1 discloses a bonded structure including: a substrate; a metal film; a semiconductor element; and an adhesive layer between the substrate and the metal film and/or between the metal film and the semiconductor element, wherein a metal contained in the metal film is diffused through stress migration, and the substrate and the semiconductor element are bonded together with the metal film therebetween. PLT 1 discloses a bonded structure sequentially including: a substrate; a first metal film; a thermal stress absorber; a second metal film; and a semiconductor element, wherein at least one of a metal contained in the first metal film and a metal contained in the second metal film is diffused through stress migration, the substrate and the thermal stress absorber are bonded together with the first metal film therebetween, and the semiconductor element and the thermal stress absorber are bonded together with the second metal film therebetween.

### CITATION LIST

### Patent Literature

PLT 1: JP6284164B

### SUMMARY OF INVENTION

### Technical Problem

The present invention aims to provide a novel technique for producing a bonded structure using direct bonding.

### Solution to Problem

Conventional solder bonding techniques cannot be used to bond fine Cu pillars due to possible solder bridges.

Conventional hybrid bonding techniques involve high-load conditions and high cost because, for example, (i) bonding is performed under vacuum, without applied pressure, and at a high temperature (300° C. to 400° C. for 2 hours), (ii) clean rooms are required, (iii) planarization by chemical mechanical polishing (CMP) is required, and (iv) expensive bonding equipment is required. In addition, it is difficult to apply such techniques to fine Cu pillar bonding due to high-load bonding conditions.

Conventional techniques (PLT 1) enable direct bonding based on stress migration using a metal film (Ag or Cu) formed by sputtering. However, with the sputtering method, it is difficult to selectively form a metal film.

The present invention encompasses the following direct bonding techniques.

### Item 1.

A bonded structure comprising a structure 1 and a structure 2 that are bonded together with a metal-plated film therebetween.

### Item 2.

The bonded structure according to Item 1, wherein a metal-plated film 1 is on the structure 1, a metal-plated film 2 is on the structure 2, and the structure 1 and the structure 2 are bonded together with the metal-plated film 1 and the metal-plated film 2 therebetween.

### Item 3.

The bonded structure according to Item 1, wherein the metal-plated film has a laminated structure including two or more metal-plated films.

### Item 4.

A method for producing a bonded structure, the method comprising:
(1) a step of forming a metal-plated film 1 on a structure 1;
(2) a step of forming a metal-plated film 2 on a structure 2;
(3) a step of stacking the structure 1 and the structure 2 in such a manner that
   (i) the metal-plated film 1 formed in step (1) and the metal-plated film 2 formed in step (2) are in contact with each other, or
   (ii) the metal-plated film 1 formed in step (1) and the metal-plated film 2 formed in step (2) are between the structures, whereby
   (iii) the structure 1 and the structure 2 are stacked face-to-face; and
(4) a step of heating the stack formed in step (3) to directly bond the metal-plated film 1 and the metal-plated film 2 together.

The bonding technique of the present invention, which uses hillocks of metal-plated films formed by electroless or electrolytic plating, has the following characteristics: (i) it is a technique to directly bond metal-plated films together using hillocks in air without applied pressure (or at a low pressure) and at a low temperature (150° C. to 250° C. for about 30 minutes); (ii) no clean rooms are required; (iii) no CMP is required; (iv) the technique is applicable to bonding of fine Cu pillars due to the absence of soldering bridges and low-load bonding conditions; (v) the technique is expected to be applicable to large-area bonding of heat sinks, direct bonded copper (DBC) substrates, IC chips, and the like; and (vi) electroless or electrolytic plating makes it possible to form metal-plated films selectively on large objects and three-dimensional objects. These characteristics result in merits such as allowing objects and materials in a wide range of fields to be directly bonded together with metal-plated films therebetween. The bonding technique of the present invention is a low-load and low-cost direct bonding technique that uses hillocks of metal-plated films.

The present invention does not require a bonding agent (solder or metal sintering material) for bonding, for example, on substrates (printed circuit boards, semiconductor wafers, semiconductor chips, etc.), and enables direct bonding of metal-plated films to each other by heat treatment (low temperature: about 150° C. to 250° C., low pressure: about 0.1 MPa to 0.4 MPa or without applied pressure, for about 30 minutes).

The bonding technique of the present invention is useful in the mounting of semiconductors.

### Advantageous Effects of Invention

The present invention can provide a novel technique for producing a bonded structure using direct bonding.

### DESCRIPTION OF EMBODIMENTS

Embodiments of the present invention will be described in detail below.

The embodiments representing the present invention are described for better understanding of the gist of the invention, and are not intended to limit the contents of the invention unless otherwise specified.

Herein, the terms “include,” “contain,” and variations thereof express concepts that encompass all of “comprise,” “consist essentially of,” and “consist of.”

Herein, when a numerical range is expressed as “A to B,” the expression means A or more and B or less.

Herein, expressions such as “part(s)” and “%” are generally used.

Herein, “part(s)” means “part(s) by mass,” and “%” means “mass % (wt %)” unless otherwise mentioned.

### 1. Bonded Structure

It is difficult to selectively form metal films and to form metal films on large objects and three-dimensional objects by sputtering (thin film production by sputter deposition or vacuum deposition) according to PLT 1.

The bonded structure of the present invention includes a structure 1 and a structure 2 that are bonded together with metal-plated films therebetween.

In the bonded structure of the present invention, preferably, the metal-plated film 1 is on the structure 1, the metal-plated film 2 is on the structure 2, and the structure 1 and the structure 2 are bonded together with the metal-plated film 1 and the metal-plated film 2 therebetween.

The direct bonding of the present invention is a bonding technique in which metal-plated films formed by electroless or electrolytic plating are bonded together. Electroless or electrolytic plating enables selective formation of metal-plated film on large objects and three-dimensional objects. Thus, the direct bonding technique of the present invention allows objects in a wide range of fields to be directly bonded together with metal-plated films therebetween.

### Structures 1 and 2

In the direct bonding technique of the present invention, the bonded structure includes a structure 1 and a structure 2 that are bonded together with metal-plated films therebetween.

Preferably, the structure 1 and the structure 2 are materials (plating-target materials) to which metal plating can be applied. Examples of plating-target materials include Cu and Cu alloys such as brass, phosphor bronze, and Corson alloys; elements such as Al, Mg, Fe, Ni, Pd, Ag, Au, Co, W, Mo, Pt, and Si and their alloys; and like other metal materials on which metal-plated films can be formed using publically known techniques.

Use of publically known techniques also enables formation of metal-plated films on nonmetals by electroless plating. Thus, the direct bonding technique of the present invention can also be applied to nonmetals.

The structure 1 and the structure 2 can be applied to all objects and materials on which metal-plated films can be formed. Examples include bumps (Cu bumps etc.), die attach materials (materials for fixing semiconductor elements (dies) with a die bonder), direct bonded aluminum (DBA) substrates, DBC substrates, ceramic substrates, cooling fins, heat sinks (parts attached to equipment for the purpose of heat dissipation and heat exhaust), lead frames (parts used in packages of semiconductor packages such as ICs and LSIs to support and fix semiconductor elements (semiconductor chips), and connect them to external wiring), passive elements (elements that consume, store, and release supplied power), and iron shafts.

### Metal-Plated Films (Including the Metal-Plated Films 1 and 2)

The present invention relates to a method for directly bonding metal-plated films together. The present invention relates to a method in which the surfaces of plating-target materials (metal or nonmetal) are plated, and the resulting metal-plated films are directly bonded together using hillocks generated due to heat treatment.

The metal-plated film may be a single layer, or may have a structure including a plurality of metal-plated films that are laminated.

In the bonded structure of the present invention, preferably, the metal-plated film 1 is on the structure 1, the metal-plated film 2 is on the structure 2, and the structure 1 and the structure 2 are bonded together with the metal-plated film 1 and the metal-plated film 2 therebetween.

Preferred metals to form the metal-plated films are nickel, cobalt, iron, indium, tin, palladium, gold, platinum, ruthenium, silver, copper, tungsten, molybdenum, rhenium, zinc, aluminum, and their alloys. More preferred metals are nickel, cobalt, palladium, silver, tungsten, molybdenum, their alloys, and the like.

Elements corresponding to the components of the plating solution are co-deposited in the metal-plated films. For example, when a reducing agent contains a boron-containing compound and/or a phosphorus-containing compound and/or a nitrogen-containing compound, boron and/or phosphorus and/or and nitrogen are co-deposited in the resulting metal-plated films.

Each metal-plated film has a structure including a single metal-plated film or a structure including a plurality of metal-plated films that are laminated.

Each metal-plated film preferably has a structure including a plurality of metal-plated films that are laminated, and more preferably has a laminated structure including two or more metal-plated films. When the metal-plated film has a structure including a plurality of metal films that are laminated, metals contained in the plurality of metal films may be of the same type or different types.

The bonded structure may be produced as follows, for example: a laminated structure of nickel and silver is formed on each of the structures 1 and 2; and a stack is formed by stacking the structure 2 on the structure 1 such that the silver layers of the laminated structures are in contact with each other.

In the case of a laminated structure including two or more metal-plated films, preferably, a bottom metal-plated film (a film adjacent to the structure) is formed by electroless Ni—P plating, electroless Ni—B plating, electroless Co—P plating, electroless Co—B plating, electroless Ni—Co—P plating, electroless Ni—Co—B plating, electroless Ni—W—P plating, electroless Ni—Mo—B plating, electroless Co—W—P plating, electroless Co—Mo—B plating, electroless Fe—B plating, electroless In plating, electroless Sn plating, electroless Pd plating, electroless Au plating, electroless Pt plating, electroless Ru plating, electroless Ag plating, electroless Cu plating, Ni electroplating, Co electroplating, Ag electroplating, or the like.

In the case of a laminated structure including two or more metal-plated films, more preferably, the bottom metal-plated film (the film adjacent to the structure) is formed by electroless Ni—P plating, electroless Ni—B plating, electroless Co—P plating, electroless Co—B plating, electroless Ni—Co—P plating, electroless Ni—Co—B plating, electroless Ni—W—P plating, electroless Ni—Mo—B plating, electroless Co—W—P plating, electroless Co—Mo—B plating, electroless Pd plating, Ni electroplating, Co electroplating, or the like.

In the case of a laminated structure including two or more metal-plated films, preferably, a top metal-plated film (an outermost film) is formed by electroless Ag plating, electroless Au plating, electroless Sn plating, electroless Cu plating, electroless Pd plating, electroless Pt plating, electroless Ru plating, or the like.

In the case of a laminated structure including two or more metal-plated films, more preferably, the top metal-plated film (the outermost film) is formed by electroless Ag plating.

Preferably, the structure including a plurality of metal-plated films that are laminated (bottom metal-plated film/top metal-plated film) is a laminated structure including metal-plated films formed by electroless Ni—P plating/electroless Ag plating, electroless Ni—B plating/electroless Ag plating, electroless Co—P plating/electroless Ag plating, electroless Co—B plating/electroless Ag plating, electroless Ni—Co—P plating/electroless Ag plating, electroless Ni—Co—B plating/electroless Ag plating, electroless Ni—W—P plating/electroless Ag plating, electroless Ni—Mo—B plating/electroless Ag plating, electroless Co—W—P plating/electroless Ag plating, electroless Co—Mo—B plating/electroless Ag plating, electroless Fe—B plating/electroless Ag plating, electroless In plating/electroless Ag plating, electroless Sn plating/electroless Ag plating, electroless Pd plating/electroless Ag plating, electroless Au plating/electroless Ag plating, electroless Pt plating/electroless Ag plating, electroless Ru plating/electroless Ag plating, electroless Ni—P plating/electroless Au plating, electroless Ni—P plating/electroless Sn plating, electroless Ni—P plating/electroless Cu plating, electroless Ni—P plating/electroless Pd plating/electroless Ag plating, electroless Ni—P plating/electroless Co—P plating/electroless Ag plating, electroless Ni—P plating/Ag electroplating, Ni electroplating/Ag electroplating, Co electroplating/Ag electroplating, or the like.

More preferably, the structure including a plurality of metal-plated films that are laminated (bottom metal-plated film/top metal-plated film) is a laminated structure including metal-plated films formed by electroless Ni—P plating/electroless Ag plating, electroless Ni—B plating/electroless Ag plating, electroless Co—P plating/electroless Ag plating, electroless Co—B plating/electroless Ag plating, electroless Ni—Co—P plating/electroless Ag plating, electroless Ni—Co—B plating/electroless Ag plating, electroless Ni—W—P plating/electroless Ag plating, electroless Ni—Mo—B plating/electroless Ag plating, electroless Co—W—P plating/electroless Ag plating, electroless Co—Mo—B plating/electroless Ag plating, electroless Fe—B plating/electroless Ag plating, electroless In plating/electroless Ag plating, electroless Sn plating/electroless Ag plating, electroless Pd plating/electroless Ag plating, electroless Au plating/electroless Ag plating, electroless Pt plating/electroless Ag plating, electroless Ru plating/electroless Ag plating, electroless Ni—P plating/electroless Pd plating/electroless Ag plating, electroless Ni—P plating/electroless Co—P plating/electroless Ag plating, electroless Ni—P plating/Ag electroplating, Ni electroplating/Ag electroplating, Co electroplating/Ag electroplating, or the like.

Even more preferably, the structure including a plurality of metal-plated films that are laminated (bottom metal-plated film/top metal-plated film) is a laminated structure including metal-plated films formed by electroless Ni—P plating/electroless Ag plating, electroless Ni—B plating/electroless Ag plating, electroless Co—P plating/electroless Ag plating, electroless Co—B plating/electroless Ag plating, electroless Ni—Co—P plating/electroless Ag plating, electroless Ni—Co—B plating/electroless Ag plating, electroless Ni—W—P plating/electroless Ag plating, electroless Ni—Mo—B plating/electroless Ag plating, electroless Co—W—P plating/electroless Ag plating, electroless Co—Mo—B plating/electroless Ag plating, electroless Ni—P plating/electroless Pd plating/electroless Ag plating, electroless Ni—P plating/electroless Co—P plating/electroless Ag plating, electroless Ni—P plating/Ag electroplating, Ni electroplating/Ag electroplating, Co electroplating/Ag electroplating, or the like.

The bottom film, when formed by electroless Ni—P plating, electroless Ni—B plating, electroless Co—P plating, electroless Co—B plating, electroless Ni—Co—P plating, electroless Ni—Co—B plating, electroless Ni—W—P plating, electroless Ni—Mo—B plating, electroless Co—W—P plating, electroless Co—Mo—B plating, electroless Pd plating, Ni electroplating, Co electroplating, or the like, acts as a barrier layer for underlying metal diffusion and is expected to be effective in preventing contamination of the top film (the outermost film).

The top film (the outermost film), when formed by electroless Ag plating or the like, contributes to effective generation of hillocks and is expected to result in a higher bonding strength.

When the metal-plated film is a single-layer structure, the metal-plated film is preferably formed by electroless Ag plating, electroless Au plating, electroless Sn plating, electroless Cu plating, electroless Pd plating, electroless Pt plating, electroless Ru plating, or the like, and is more preferably formed by electroless Ag plating.

For excellent bonding strength, the metal-plated film thickness is preferably 0.01 μm or more and 20 μm or less, more preferably 0.05 μm or more and 10 μm or less, and even more preferably 0.1 μm or more and 5 μm or less. In the case of a laminated structure including two or more metal-plated films, the metal-plated film thickness is the total thickness of the laminated structure. When the metal-plated film is a single-layer structure, the metal-plated film thickness is the thickness of the single layer.

### 2. Method for Producing a Bonded Structure

The method for producing a bonded structure of the present invention includes:
(1) a step of forming a metal-plated film 1 on a structure 1;
(2) a step of forming a metal-plated film 2 on a structure 2;
(3) a step of stacking the structure 1 and the structure 2 in such a manner that
   (i) the metal-plated film 1 formed in step (1) and the metal-plated film 2 formed in step (2) are in contact with each other, or
   (ii) the metal-plated film 1 formed in step (1) and the metal-plated film 2 formed in step (2) are between the structures, whereby
   (iii) the structure 1 and the structure 2 are stacked face-to-face; and
(4) a step of heating the stack formed in step (3) to directly bond the metal-plated film 1 and the metal-plated film 2 together.

When the structures 1 and 2 are substrate silicon wafers ( ) the method for producing a bonded structure of the present invention includes forming bumps on the substrate and forming metal-plated films on the bumps. The bumps are preferably Cu pillar bumps.

### (1) Step of Forming the Metal-Plated Film 1 on the Structure 1

### (2) Step of Forming the Metal-Plated Film 2 on the Structure 2

Plating is applied to the structure 1 to form the metal-plated film 1 thereon. Plating is applied to the structure 2 to form the metal-plated film 2 thereon. Plating can be applied several times. Any plating method may be used, with electrolytic plating (electroplating) and/or electroless plating being preferred, and electroless plating being more preferred.

Preferably, the structure 1 and the structure 2 are materials (plating-target materials) to which metal plating can be applied. Examples of plating-target materials include Cu and Cu alloys such as brass, phosphor bronze, and Corson alloys; elements such as Al, Mg, Fe, Ni, Pd, Ag, Au, Co, W, Mo, Pt, and Si and their alloys; and like other metal-based materials that can form metal-plated films using publically known techniques.

Preferably, the metal-plated films 1 and 2 each have a structure including a plurality of (i.e., two or more) metal-plated films that are laminated.

The structure 1, the metal-plated film 1, the structure 2, and the metal-plated film 2 are as described above.

For example, metal layers are formed on the surfaces of the structures 1 and 2 (for example, Cu bumps are formed on semiconductor chips by Cu electroplating or forming Cu patterns on a ceramic substrate using the direct bonding method or the active metal bonding method). Then, electroless Ni—P-plated films are formed using an electroless nickel-phosphorus plating (Ni—P plating) bath. Preferably, the step of forming electroless Ni—P-plated films on the plating-target materials using an electroless Ni—P plating bath includes immersing the plating-target materials in the electroless Ni—P plating bath.

For example, when forming films by nickel (Ni) plating, electroless plating is preferred. In electroless Ni—P plating, nickel ions are autocatalytically or chemically reduced to nickel and then deposited on the substrate. Electroless Ni—P plating can be applied to any plating-target material that can be plated with nickel. The total thickness of the electroless Ni—P-plated films is preferably 0.01 μm or more and 20 μm or less.

Then, the plating-target material with the electroless Ni—P-plated films formed thereon is immersed in an electroless Ag plating bath, allowing the plating-target material to be plated with Ag. Preferably, Ag plating is applied to a thickness of 0.01 μm or more and 20 μm or less.

(3) Step of Stacking the Structure 1 and the Structure 2 in Such a Manner that (i) the Metal-Plated Film 1 Formed in Step (1) and the Metal-Plated Film 2 Formed in Step (2) are in Contact with Each Other, or (ii) the Metal-Plated Film 1 Formed in Step (1) and the Metal-Plated Film 2 Formed in Step (2) are Between the Structures, Whereby (iii) the Structure 1 and the Structure 2 are Stacked Face-to-Face (Formation of a Stack)

The structure 1 and the structure 2 are stacked to form a stack in such a manner that the metal-plated film 1 formed on the surface of structure 1 and the metal-plated film 2 formed on the surface of the structure 2 are in contact with each other.

The structure 1 and the structure 2 are stacked to form a stack in such a manner that the metal-plated film 1 formed on the surface of structure 1 and the metal-plated film 2 formed on the surface of the structure 2 are between the structures.

Preferably, the bonded structure includes metal films including a plurality of metal-plated films 1 and a plurality of metal-plated films 2 that are laminated.

### (4) Step of Heating the Stack Formed in Step (3) to Directly Bond the Metal-Plated Film 1 and the Metal-Plated Film 2 Together

In the step of direct bonding, the stack is heated so as to bond together a metal in the metal-plated film 1 formed on the surface of the structure 1 and a metal in the metal-plated film 2 formed on the surface of the structure 2.

The bonding technique uses hillocks formed by plating. A specific embodiment is a method for directly bonding metal-plated films together. The present invention relates to a method in which the surfaces of plating-target materials (metal or nonmetal) are plated, and the resulting metal-plated films are directly bonded together using hillocks generated due to heat treatment. Hillocks are hemispherical protrusions that appear on the surfaces of thin metal films. Hillocks are generated when a thin metal film undergoes local plastic deformation due to compressive stress applied to the surface of the thin metal film caused by heating or the like.

The heating temperature of the stack is appropriately adjusted based on the materials of the structure 1, the metal-plated film 1, the structure 2, and the metal-plated film 2. The stack is heated for direct bonding at a temperature of preferably 100° C. or higher and 400° C. or lower, more preferably 150° C. or higher and 300° C. or lower, and even more preferably 150° C. or higher and 250° C. or lower. The temperature to heat the stack for direct bonding is preferably 100° C. or higher and 400° C. or lower. Since the metal-plated films formed on the structures by plating are directly bonded together using hillocks generated by heat treatment, the bonding can be successfully achieved even when heating is performed at a low temperature of 250° C. or lower.

The pressure applied when bonding the stack is appropriately adjusted based on the materials of the structure 1, the metal-plated film 1, the structure 2, and the metal-plated film 2. Preferably, the stack is heated in air at a low pressure or without applied pressure for direct bonding. Regarding the pressure applied when bonding the stack, it is possible to reduce the pressure applied during direct bonding. The pressure can be reduced preferably to the level that no pressure is applied or to a pressure of 1 MPa or less, or more preferably to the level that no pressure is applied or to a low pressure of about 0.1 MPa to 0.4 MPa.

The atmosphere in which the stack is heated for direct bonding is appropriately adjusted based on the materials of the structure 1, the metal-plated film 1, the structure 2, and the metal-plated film 2. A preferred atmosphere may be an air or vacuum atmosphere. Preferably, the atmosphere in which the direct bonding is performed may be an inert atmosphere (e.g., argon gas, nitrogen gas, etc.) or a reduced atmosphere (hydrogen gas, formic acid gas, etc.).

The reaction time to heat the stack for direct bonding is appropriately adjusted based on the materials of the structure 1, the metal-plated film 1, the structure 2, and the metal-plated film 2. The stack is heated for direct bonding for preferably 5 minutes or more and 3 hours or less, more preferably 10 minutes or more and 2 hours or less, and even more preferably 15 minutes or more and 1 hour or less (about 30 minutes).

The bonding technique of the present invention, which uses hillocks of metal-plated films formed by electroless or electrolytic plating, has the following characteristics: (i) it is a technique to directly bond metal-plated films together using hillocks in air without applied pressure (or at a low pressure) and at a low temperature (150° C. to 250° C. for about 30 minutes); (ii) no clean rooms are required; (iii) no CMP is required; (iv) the technique is applicable to bonding of fine Cu pillars due to the absence of soldering bridges and low-load bonding conditions; (v) the technique is expected to be applicable to large-area bonding of heat sinks, DBC substrates, IC chips, and the like; and (vi) electroless or electrolytic plating makes it possible to form metal-plated films selectively on large objects and three-dimensional objects. These characteristics result in merits such as allowing objects and materials in a wide range of fields to be directly bonded together with metal-plated films therebetween. The bonding technique of the present invention is a low-load and low-cost direct bonding technique that uses hillocks of metal-plated films.

The present invention does not require a bonding agent (solder or metal sintering material) for bonding, for example, on substrates (printed circuit boards, semiconductor wafers, semiconductor chips, etc.), and enables direct bonding of metal-plated films to each other by heat treatment (low temperature: about 150° C. to 250° C., low pressure: about 0.1 MPa to 0.4 MPa or without applied pressure, for about 30 minutes).

The bonding technique of the present invention is useful in the mounting of semiconductors.

### EXAMPLES

The present invention is specifically described below with reference to Examples.

The present invention is not limited to the following specific Examples.

### 1. Method for Producing a Bonded Structure

### Example 1

### (1) Step of Forming a Metal-Plated Film 1 on a Structure 1

Sample A: As a structure 1 (substrate), a silicon wafer including Cu pillars (bumps 1) was prepared, and electroless Ni—P plating was applied to a thickness of 0.1 μm on the Cu pillars selectively (in a patterned form). Then, electroless Ag plating was applied to a thickness of 0.2 μm (a metal-plated film 1).

### (2) Step of Forming a Metal-Plated Film 2 on a Structure 2

Sample B: As a structure 2 (substrate), a silicon wafer fully plated with Cu was prepared, and electroless Ni—P plating was applied thereto to a thickness of 0.1 μm. Then, electroless Ag plating was applied thereto to a thickness of 0.2 μm (a metal-plated film 2).

(3) Step of Stacking the Structure 1 and the Structure 2 in Such a Manner that (i) the Metal-Plated Film 1 Formed in Step (1) and the Metal-Plated Film 2 Formed in Step (2) are in Contact with Each Other, or (ii) the Metal-Plated Film 1 Formed in Step (1) and the Metal-Plated Film 2 Formed in Step (2) are Between the Structures, Whereby (iii) the Structure 1 and the Structure 2 are Stacked Face-to-Face (Formation of a Stack)

The metal-plated film of sample A and the metal-plated film of sample B were stacked in contact with each other (a stack).

### (4) Step of Heating the Stack Formed in Step (3) to Directly Bond the Metal-Plated Film 1 and the Metal-Plated Film 2 Together

The stack was heat-treated in air without applied pressure at 250° C. for 30 minutes, whereby a bonded structure of Example 1 was obtained.

Table 3: SEM observation of a cross-section of the bonded structure of Example 1 confirmed successful bonding, with the occurrence of bonding defects (e.g., voids or cracks) being suppressed.

### Examples 2 to 17

The procedure of Example 1 was repeated except that the electroless Ni—P plating applied to sample A and sample B in Example 1 was changed to the following types of electroless plating baths, whereby bonded structures of Example 2 to 17 were obtained. SEM observation of cross-sections of the bonded structures of Examples 2 to 17 confirmed successful bonding, with the occurrence of bonding defects being suppressed.
Example 2: electroless Ni—B plating
Example 3: electroless Co—P plating
Example 4: electroless Co—B plating
Example 5: electroless Ni—Co—P plating
Example 6: electroless Ni—Co—B plating
Example 7: electroless Ni—W—P plating
Example 8: electroless Ni—Mo—B plating
Example 9: electroless Co—W—P plating
Example 10: electroless Co—Mo—B plating
Example 11: electroless Fe—B plating
Example 12: electroless In plating
Example 13: electroless Sn plating
Example 14: electroless Pd plating
Example 15: electroless Au plating
Example 16: electroless Pt plating
Example 17: electroless Ru plating

### Examples 18 to 20

The procedure of Example 1 was repeated except that the electroless Ag plating applied to sample A and sample B in Example 1 was changed to the following types of electroless plating baths, whereby bonded structures of Example 18 to 20 were obtained. SEM observation of cross-sections of the bonded structures of Examples 18 to 20 confirmed successful bonding, with the occurrence of bonding defects being suppressed.
Example 18: electroless Au plating
Example 19: electroless Sn plating
Example 20: electroless Cu plating

### Example 21

The procedure of Example 1 was repeated except that the electroless Ni—P-plated film thickness of sample A and sample B in Example 1 was changed from 0.1 μm to 3.0 μm, whereby a bonded structure of Example 21 was obtained. SEM observation of a cross-section of the bonded structure of Example 21 confirmed successful bonding, with the occurrence of bonding defects being suppressed.

### Example 22

The procedure of Example 1 was repeated except that the electroless Ag-plated film thickness of the sample A and sample B in Example 1 was changed from 0.2 μm to 1.0 μm, whereby a bonded structure of Example 22 was obtained. SEM observation of a cross-section of the bonded structure of Example 22 confirmed successful bonding, with the occurrence of bonding defects being suppressed.

### Example 23

The procedure of Example 1 was repeated except that the laminated structure of the metal-plated films of sample A and sample B in Example 1 was changed to a three-layer structure including a 0.1-μm-thick electroless Ni—P-plated film, a 0.1-μm thick electroless Pd-plated film, and a 0.2-μm-thick electroless Ag-plated film, whereby a bonded structure of Example 23 was obtained. SEM observation of a cross-section of the bonded structure of Example 23 confirmed successful bonding, with the occurrence of bonding defects being suppressed.

### Example 24

The procedure of Example 1 was repeated except that the laminated structure of the metal-plated films of sample A and sample B in Example 1 was changed to a three-layer structure including a 0.1-μm-thick electroless Ni—P-plated film, a 0.1-μm thick electroless Co—P-plated film, and a 0.2-μm-thick electroless Ag-plated film, whereby a bonded structure of Example 24 was obtained. SEM observation of a cross-section of the bonded structure of Example 24 confirmed successful bonding, with the occurrence of bonding defects being suppressed.

### Example 25

The procedure of Example 1 was repeated except that the heat treatment conditions with a heating temperature of 250° C. for 30 minutes in Example 1 were changed to a heating temperature of 200° C. for 30 minutes, whereby a bonded structure of Example 25 was obtained. SEM observation of a cross-section of the bonded structure of Example 25 confirmed successful bonding, with the occurrence of bonding defects being suppressed.

### Example 26

Sample A: As a structure (substrate), a silicon wafer fully plated with Cu (without bumps) was prepared, and electroless Ni—P plating was applied thereto to a thickness of 0.1 μm. Then, electroless Ag plating was applied thereto to a thickness of 0.2 μm (a metal-plated film 1). Two pieces of sample A (structures 1 and 2) were prepared. The procedure of Example 1 was repeated to obtain a bonded structure of Example 26. SEM observation of a cross-section of the bonded structure of Example 26 confirmed successful bonding, with the occurrence of bonding defects being suppressed.

### Example 27

Sample A: As a structure (substrate), a silicon wafer fully plated with Cu (without bumps) was prepared, and Ni electroplating was applied thereto to a thickness of 0.1 μm. Then, Ag electroplating was applied thereto to a thickness of 0.2 μm (a metal-plated film 1). Two pieces of sample A were prepared (structures 1 and 2). The procedure of Example 1 was repeated to obtain a bonded structure of Example 27. SEM observation of a cross-section of the bonded structure of Example 27 confirmed successful bonding, with the occurrence of bonding defects being suppressed.

### Example 28

Sample A: As a structure (substrate), a silicon wafer fully plated with Cu (without bumps) was prepared, and Co electroplating was applied thereto to a thickness of 0.1 μm. Then, Ag electroplating was applied thereto to a thickness of 0.2 μm (a metal-plated film 1). Two pieces of sample A (structures 1 and 2) were prepared. The procedure of Example 1 was repeated to obtain a bonded structure of Example 28. SEM observation of a cross-section of the bonded structure of Example 28 confirmed successful bonding, with the occurrence of bonding defects being suppressed.

### Examples 1 to 28

The bottom film, when formed by electroless Ni—P plating, electroless Ni—B plating, electroless Co—P plating, electroless Co—B plating, electroless Ni—Co—P plating, electroless Ni—Co—B plating, electroless Ni—W—P plating, electroless Ni—Mo—B plating, electroless Co—W—P plating, electroless Co—Mo—B plating, electroless Pd plating, Ni electroplating, Co electroplating, or the like, acts as a barrier layer for underlying metal diffusion and is expected to be effective in preventing contamination of the top film (the outermost film).

The top film (the outermost film), when formed by electroless Ag plating or the like, contributes to effective generation of hillocks and is expected to result in a higher bonding strength.

### Example 29, Single-Layer Electroless-Ag-Plated Structure

For sample A and sample B in Example 1, the procedure of Example 1 was repeated except that the laminated structure of the metal-plated films was changed to a 0.2-μm-thick single-layer electroless-Ag-plated structure, whereby a bonded structure of Example 29 was obtained. SEM observation of a cross-section of the bonded structure of Example 29 showed no occurrence of significant bonding defects and confirmed that even a single-layer plated structure is acceptable for bonding.

### Example 30, Single-Layer Electroless-Au-Plated Structure

For sample A and sample B in Example 1, the procedure of Example 1 was repeated except that the laminated structure of the metal-plated films was changed to a 0.2-μm-thick single-layer electroless-Au-plated structure, whereby a bonded structure of Example 30 was obtained. SEM observation of a cross-section of the bonded structure of Example 30 showed no occurrence of significant bonding defects and confirmed that even a single-layer plated structure is acceptable for bonding.

### Example 31, Single-Layer Electroless-Sn-Plated Structure

For sample A and sample B in Example 1, the procedure of Example 1 was repeated except that the laminated structure of the metal-plated films was changed to a 0.2-μm-thick single-layer electroless-Sn-plated structure, whereby a bonded structure of Example 31 was obtained. SEM observation of a cross-section of the bonded structure of Example 31 showed no occurrence of significant bonding defects and confirmed that even a single-layer plated structure is acceptable for bonding.

### Example 32, Single-Layer Electroless Cu-Plated Structure

For sample A and sample B in Example 1, the procedure of Example 1 was repeated except that the laminated structure of the metal-plated films was changed to a 0.2-μm-thick single-layer electroless-Cu-plated structure, whereby a bonded structure of Example 32 was obtained. SEM observation of a cross-section of the bonded structure of Example 32 showed no occurrence of significant bonding defects and confirmed that even a single-layer plated structure is acceptable for bonding.

### Comparative Example 1 without Metal-Plated Films

The procedure of Example 1 was repeated except that no metal plating was applied, whereby a bonded structure of Comparative Example 1 was obtained. As shown in Table 2, SEM observation of a cross-section of the bonded structure of Comparative Example 1 showed the occurrence of bonding defects and confirmed that the bonding was not successfully achieved.

TABLE 1
Test Results

| | | Film | | |
|---|---|---|---|---|
| Conditions | Structure of metal-plated films | thickness | Bonding | Bonding |
| Example (bottom film/top film laminated structure) | | (μm) | conditions | results |
| 1 | Electroless Ni—P/electroless Ag plating | 0.1/0.2 | 250° C. | Successful |
| 2 | Electroless Ni—B/electroless Ag plating | 0.1/0.2 | 30 min | |
| 3 | Electroless Co—P/electroless Ag plating | 0.1/0.2 | | |
| 4 | Electroless Co—B/electroless Ag plating | 0.1/0.2 | | |
| 5 | Electroless Ni—Co—P/electroless Ag plating | 0.1/0.2 | | |
| 6 | Electroless Ni—Co—B/electroless Ag plating | 0.1/0.2 | | |
| 7 | Electroless Ni—W—P/electroless Ag plating | 0.1/0.2 | | |
| 8 | Electroless Ni—Mo—B/electroless Ag plating | 0.1/0.2 | | |
| 9 | Electroless Co—W—P/electroless Ag plating | 0.1/0.2 | | |
| 10 | Electroless Co—Mo—B/electroless Ag plating | 0.1/0.2 | | |
| 11 | Electroless Fe—B/electroless Ag plating | 0.1/0.2 | | |
| 12 | Electroless In/electroless Ag plating | 0.1/0.2 | | |
| 13 | Electroless Sn/electroless Ag plating | 0.1/0.2 | | |
| 14 | Electroless Pd/electroless Ag plating | 0.1/0.2 | | |
| 15 | Electroless Au/electroless Ag plating | 0.1/0.2 | | |
| 16 | Electroless Pt/electroless Ag plating | 0.1/0.2 | | |
| 17 | Electroless Ru/electroless Ag plating | 0.1/0.2 | | |
| 18 | Electroless Ni—P/electroless Au plating | 0.1/0.2 | | |
| 19 | Electroless Ni—P/electroless Sn plating | 0.1/0.2 | | |
| 20 | Electroless Ni—P/electroless Cu plating | 0.1/0.2 | | |
| 21 | Electroless Ni—P/electroless Ag plating | 3.0/0.2 | | |
| 22 | Electroless Ni—P/electroless Ag plating | 0.1/1.0 | | |
| 23 | Electroless Ni—P/electroless Pd/electroless Ag plating | 0.1/0.1/0.2 | | |
| 24 | Electroless Ni—P/electroless Co—P/electroless Ag plating | 0.1/0.1/0.2 | | |
| 25 | Electroless Ni—P/electroless Ag plating | 0.1/0.2 | 200° C. | |
| | | | 30 min | |
| 26 | Electroless Ni—P plating/Ag electroplating | 0.1/0.2 | 250° C. | |
| 27 | Ni electroplating/Ag electroplating | 0.1/0.2 | 30 min | |
| 28 | Co electroplating/Ag electroplating | 0.1/0.2 | | |

TABLE 2
Test Results

| Conditions | Structure of metal-plated films | Film thickness | Bonding | |
|---|---|---|---|---|
| Example (single-layer structure) | | (μm) | conditions | Bonding results |
| 29 | Electroless Ag plating | 0.2 | 250° C. | Acceptable |
| 30 | Electroless Au plating | 0.2 | 30 min | |
| 31 | Electroless Sn plating | 0.2 | | |
| 32 | Electroless Cu plating | 0.2 | | |
| Comparative Example | | | | |
| 1 | No electroless plating applied | — | 250° C. | Bonding defects were found |
| | (remained as Cu) | | 30 min | |

### 2. Industrial Applicability

The present invention relates to a method for directly bonding metal-plated films together. The present invention relates to a method in which the surfaces of plating-target materials (metal or nonmetal) are plated, and the resulting metal-plated films are directly bonded together using hillocks generated due to heat treatment.

The bonding technique of the present invention, which uses hillocks of metal-plated films formed by electroless or electrolytic plating, has the following characteristics: (i) it is a technique to directly bond metal-plated films together using hillocks in air without applied pressure (or at a low pressure) and at a low temperature (150° C. to 250° C. for about 30 minutes); (ii) no clean rooms are required; (iii) no CMP is required; (iv) the technique is applicable to bonding of fine Cu pillars due to the absence of soldering bridges and low-load bonding conditions; (v) the technique is expected to be applicable to large-area bonding of heat sinks, DBC substrates, IC chips, and the like; and (vi) electroless or electrolytic plating makes it possible to form metal-plated films selectively on large objects and three-dimensional objects. These characteristics result in merits such as allowing objects and materials in a wide range of fields to be directly bonded together with metal-plated films therebetween. The bonding technique of the present invention is a low-load and low-cost direct bonding technique that uses hillocks of metal-plated films.

The present invention does not require a bonding agent (solder or metal sintering material) for bonding, for example, on substrates (printed circuit boards, semiconductor wafers, semiconductor chips, etc.), and enables direct bonding of metal-plated films to each other by heat treatment (low temperature: about 150° C. to 250° C., low pressure: about 0.1 MPa to 0.4 MPa or without applied pressure, for about 30 minutes).

The bonding technique of the present invention is useful in the mounting of semiconductors.

1. A bonded structure comprising a structure 1 and a structure 2 that are bonded together with a metal-plated film therebetween.

2. The bonded structure according to claim 1, wherein a metal-plated film 1 is on the structure 1, a metal-plated film 2 is on the structure 2, and the structure 1 and the structure 2 are bonded together with the metal-plated film 1 and the metal-plated film 2 therebetween.

3. The bonded structure according to claim 1,
wherein the metal-plated film has a laminated structure including two or more metal-plated films.

4. A method for producing a bonded structure, the method comprising:
(1) a step of forming a metal-plated film 1 on a structure 1;
(2) a step of forming a metal-plated film 2 on a structure 2;
(3) a step of stacking the structure 1 and the structure 2 in such a manner that
(i) the metal-plated film 1 formed in step (1) and the metal-plated film 2 formed in step (2) are in contact with each other, or
(ii) the metal-plated film 1 formed in step (1) and the metal-plated film 2 formed in step (2) are between the structures, whereby
(iii) the structure 1 and the structure 2 are stacked face-to-face; and
(4) a step of heating the stack formed in step (3) to directly bond the metal-plated film 1 and the metal-plated film 2 together.
